(19) United States
(12) Patent Application Publication
(10) Pub. No.: US 2009/0261452 A1
(43) Pub. Date: Oct. 22, 2009

(54) SEMICONDUCTOR DEVICE INCLUDING AN INDUCTOR ELEMENT

(76) Inventors: Kouichi TSUJIMOTO, Osaka (JP); Yukio Hiraoka, Hyogo (JP)

Correspondence Address: MCDERMOTT WILL & EMERY LLP, 600 13TH STREET, NW, WASHINGTON, DC, 20005-3096, US

(21) Appl. No.: 12/367,061

(22) Filed: Feb. 6, 2009

(30) Foreign Application Priority Data
Apr. 18, 2008 (JP) 2008-109311

(51) Int. Cl. H01L 29/82; H01F 27/30

(52) U.S. Cl. 257/531; 336/188; 257/E29.323

(57) ABSTRACT

An inductor element is formed in a spiral shape so as to have a plurality of windings which cross each other three-dimensionally at least in one intersection on a substrate. Each of the plurality of windings is formed by a first wiring formed on the substrate with a first insulating film interposed therebetween and a second wiring formed on the first wiring with a second insulating film interposed therebetween. The first wiring and the second wiring are electrically connected to each other in a region other than the intersection of the plurality of windings through an opening formed in the second insulating film. A lower wire segment in the intersection is formed only by the first wiring by separating the second wiring in the intersection. An upper wire segment in the intersection is formed only by the second wiring by separating the first wiring in the intersection.

### CROSS-REFERENCE TO RELATED APPLICATIONS

This application claims priority under 35 U.S.C. §119(a) on Japanese Patent Application No. 2008-109311 filed on Apr. 18, 2008, the entire contents of which are hereby incorporated by reference.

### BACKGROUND OF THE INVENTION

1. Field of the Invention

The present invention relates to a semiconductor device including an inductor element that is formed in a spiral shape so as to have a plurality of windings.

2. Related Art

Recently, wireless systems such as cellular phones and PDAs (Personal Digital Assistances) have been widely used and have increasingly progressed. There has been a growing demand for higher performance and reduction in size of high-frequency circuits having a wireless system. With such a demand, high-performance passive elements such as resistors, capacitors, and inductors have been increasingly on-chip mounted on semiconductor devices. However, the passive elements on-chip mounted on the semiconductor devices are more susceptible to coupling noise with a substrate and other parasitic effects as the circuit operation frequency increases. This causes degradation in performance of the passive elements, resulting in increase in power consumption and cost. As a result, system characteristics cannot be improved.

Inductors as inductive elements have been widely used in impedance matching, RF (Radio Frequency) filters, RF transceivers, voltage control oscillators, power amplifiers, RF amplifier circuits for low-noise amplifiers, and the like.

Moreover, spiral inductor elements having windings formed by a wiring process have been increasingly on-chip mounted on semiconductor devices. Such a spiral inductor element has both terminals on the same plane. Therefore, when the spiral inductor element has two or more windings, the windings need to be arranged so as to cross each other three-dimensionally.

Hereinafter, a conventional spiral inductor element will be described with reference to the accompanying drawings. FIGS. 6 and 7 show a structure of a conventional spiral inductor element. FIG. 6 is a plan view of the inductor element and FIG. 7 is a cross-sectional view taken along line VII-VII in FIG. 6. The inductor element shown in FIGS. 6 and 7 is a two-turn inductor using a wire arranged in a spiral shape on a semiconductor substrate as windings. In this inductor element, both terminals are provided on the same plane and extended to respective connection pads. The windings cross each other at one intersection.

More specifically, as shown in FIGS. 6 and 7, an integrated circuit (not shown) having a predetermined function is provided on a top surface of a silicon substrate 1, and connection pads 2b and 2c are provided in the periphery of the top surface of the silicon substrate 1 so as to be connected to the integrated circuit. The connection pads 2b and 2c are connected to both ends of the inductor element 13, respectively, and are located adjacent to each other. An insulating film 3 made of, for example, silicon oxide is formed on the top surface of the silicon substrate 1 except the respective central portions of the connection pads 2b and 2c. The central portions of the connection pads 2b and 2c are exposed through openings 4 formed in the insulating film 3, respectively. A protective film (insulating film) 5 made of, for example, a polyimide resin is formed over the top surface of the insulating film 3. Openings 6 are formed in the protective film 5 at respective positions corresponding to the openings 4 of the insulating film 3. Underlying metal layers 11, 12, an outer underlying metal layer 17, and an inner underlying metal layer 18 are formed over the top surface of the protective film 5 by using copper or the like. A first lead-out wiring 8 and a second lead-out wiring 9 which are made of, for example, copper are formed over the entire top surface of the underlying metal layers 11, 12. An outer upper-layer wiring 14 and an inner upper-layer wiring 15 are formed over the entire top surface of the outer underlying metal layer 17 and the inner underlying metal layer 18. A seal film 22 made of, for example, an epoxy resin is formed over the protective film 5 so as to cover the first lead-out wiring 8, the second lead-out wiring 9, the outer upper-layer line 14, and the inner upper-layer line 15.

The inductor element 13 has a two-turn spiral structure and has one three-dimensional intersection. The inductor element 13 has the outer upper-layer wiring 14, the inner upper-layer wiring 15, the first and second lead-out wiring 8 and 9, and a linear lower-layer wiring 16. The outer upper-layer wiring 14 is formed over the protective film 5 and has a partially missing annular (regular octagonal) shape. The inner upper-layer line 15 is formed inside the outer upper-layer wiring 14 over the protective film 5 and has a partially missing annular (regular octagonal) shape. The missing part of the regular octagonal shape of the inner upper-layer line 15 is located on the same side as that of the missing part of the regular octagonal shape of the outer upper-layer wiring 14. The linear lower-layer wiring 16 is formed on the top surface of the silicon substrate 1 in a region corresponding to one end of the inner upper-layer wiring 15. The lower-layer wiring 16 is made of, for example, an aluminum-based metal. For example, the lower-layer wiring 16 may be formed in advance in the integrated circuit formed on the top surface of the silicon substrate 1.

One end of the outer upper-layer wiring 14 including the outer underlying metal layer 17 is connected to the other end of the first lead-out wiring 8 including the second underlying metal layer 11. The other end of the outer upper-layer wiring 14 including the outer underlying metal layer 17 is connected to one end of the lower-layer wiring 16 through an opening (through hole) 19 formed in the insulating film 3 and the protective film 5. One end of the inner upper-layer wiring 15 including the inner underlying metal layer 18 is connected to the other end of the second lead-out wiring 9 including the third underlying metal layer 12, and the other end of the inner upper-layer wiring 15 including the inner underlying metal layer 18 is connected to the other end of the lower-layer wiring 16 through an opening 20 formed in the insulating film 3 and the protective film 5.

One end of the first lead-out wiring 8 including the second underlying metal layer 11 is connected to the connection pad 2b through the openings 4, 6 in the insulating film 3 and the protective film 5, and one end of the second lead-out wiring 9 including the third underlying metal layer 12 is connected to the connection pad 2c through the openings 4, 6 in the insulating film 3 and the protective film 5.

[Patent Document 1] Japanese Patent Laid-Open Publication No. 2007-165761

### SUMMARY OF THE INVENTION

Characteristics of a typical spiral inductor element will now be described. For example, in a series resonant LC circuit, Q-factor (quality factor) can be calculated by dividing an inductor value at a resonance frequency by a series resistance value of the circuit according to the formula (1):

Q=ωL/R (1)

where ω is 2πf, π is a ratio of the circumference of a circle to its diameter, f is a frequency, L is an inductance value, and R is a resistance value.

It is considered that a higher Q-factor inductor element has better electric characteristics. The Q-factor is therefore a factor that improves performance such as current consumption and phase noise of an RF circuit.

However, spiral inductor elements have properties which are significantly different from those of an ideal inductive element due to resistance loss of a wiring forming windings, resistance loss in a substrate, capacitive coupling between a wiring forming windings and the substrate, and the like. Accordingly, spiral inductor elements generally have poor performance. More specifically, although spiral inductor elements are set to have the maximum Q-factor at a required operation frequency, the inductance value is reduced due to the various losses described above, and therefore the Q-factor is reduced. It has therefore been desired to increase the Q-factor of the spiral inductor elements by suppressing the losses described above.

Hereinafter, problems of the conventional spiral inductor element shown in FIGS. 6 and 7 will be described. In the conventional spiral inductor element shown in FIGS. 6 and 7, the lower layer wiring 16 at the intersection of windings is formed on the silicon substrate 1. Accordingly, when a magnetic field is abruptly changed in the vicinity of the substrate, an eddy current is generated also in the silicon substrate 1 due to the electromagnetic induction effect. Loss resulting from the eddy current is therefore generated, causing reduction in Q-factor indicating inductor characteristics and heat generation. This eddy current is more likely to be generated as the specific resistance of the substrate decreases. Moreover, as the operation frequency increases, the influence of the eddy current on inductor characteristics increases, whereby problems are more likely to occur.

As shown in FIG. 7, in the conventional spiral inductor element, the lower-layer wiring 16 at the intersection is close to the silicon substrate 1. Therefore, the substrate-wiring parasitic capacitance increases, resulting in capacitance loss. As a result, the Q-factor is reduced at a high frequency and the self resonant frequency is reduced. Reduction in self resonant frequency especially causes reduction in margin of operation and performance of the RF circuit.

In view of the above, it is an object of the present invention to provide a high performance, high frequency spiral inductor element in which windings cross each other and which is capable of suppressing loss due to an eddy current generated in a substrate when a current flows in a lower-layer wiring at an intersection of the windings and is capable of having a high self resonant frequency and a high Q-factor.

In order to achieve the above object, a semiconductor device according to the present invention is a semiconductor device including an inductor element formed on a semiconductor substrate. The inductor element is formed in a spiral shape so as to have a plurality of windings which cross each other three-dimensionally at least in one intersection on the semiconductor substrate. Each of the plurality of windings is formed by a first wiring formed on the semiconductor substrate with a first insulating film interposed therebetween and a second wiring formed on the first wiring with a second insulating film interposed therebetween. The first wiring and the second wiring are electrically connected to each other in a region other than the intersection of the plurality of windings through an opening formed in the second insulating film. A lower wire segment in the intersection is formed only by the first wiring by separating the second wiring in the intersection. An upper wire segment in the intersection is formed only by the second wiring by separating the first wiring in the intersection. The first wiring of the lower wire segment and the second wiring of the upper wire segment are electrically insulated from each other by the second insulating film.

According to the semiconductor device of the present invention, the first wiring formed on the semiconductor substrate with the first insulating film interposed therebetween and the second wiring formed on the first wiring with the second insulating film interposed therebetween are electrically connected to each other through the opening formed in the second insulating film. Each winding of the inductor element is thus structured. Therefore, by separating the second wiring in the intersection, the lower wire segment in the intersection can be formed by the first wiring, that is, the wiring formed on the semiconductor substrate with the first interlayer insulating film interposed therebetween. Since the first wiring can be isolated from the semiconductor substrate, an eddy current generated in the substrate can be suppressed, whereby loss resulting from the eddy current can be suppressed. As a result, a high Q-factor inductor element can be implemented. Moreover, since the first wiring serving as the lower wire segment in the intersection can be isolated from the semiconductor substrate, the substrate-wiring parasitic capacitance can be reduced, whereby the influence of capacitive coupling can be suppressed. As a result, an inductor element having a high self resonant frequency can be implemented.

According to the semiconductor device of the present invention, each winding of the inductor element has a two-layer structure of the first wiring and the second wiring. Accordingly, the series resistance of each winding can be reduced, whereby loss resulting from the resistance can be significantly reduced. As a result, the self resonant frequency and the Q-factor of the inductor element can further be improved, whereby a high performance high frequency inductor element can be implemented. Performance, power consumption, and the like of RF circuits such as oscillators and low noise amplifiers can therefore be improved.

In the semiconductor device of the present embodiment, a third wiring may be formed between the semiconductor substrate and the first insulating film. In this case, the third wiring can be used as a tap terminal by, for example, extending one portion of the windings to the third wiring.

The semiconductor device of the present invention may further includes a tap terminal formed by extending at least one portion of the plurality of windings to a wiring of a layer lower than that of the first wiring or to a wiring of a layer higher than that of the second wiring. In this case, by, for example, providing the tap terminal at a midpoint between one end and another end of the inductor element, two inductors having excellent characteristics such as a high Q-factor and a high self resonant frequency and having similar characteristics to each other can be easily implemented between one end and the tap terminal and between another end and the tap terminal.

In the semiconductor device of the present invention, it is preferable that the first wiring of the lower wire segment and the second wiring of the upper wire segment have a substantially same electric resistance. In this case, since the electric resistance (series resistance) of the lower wire segment in the intersection is equal to the electric resistance (series resistance) of the upper wire segment in the intersection, respective Q-factor losses resulting from the resistance become equal to each other when viewed from both ends of the inductor element. A high-frequency inductor element having excellent symmetry can therefore be implemented. Note that in order to make the electric resistance of the first wiring as the lower wire segment substantially equal to that of the second wiring as the upper wire segment, for example, the first wiring of the lower wire segment and the second wiring of the upper wire segment may be made of substantially a same material with substantially same dimensions.

As has been described above, according to the present invention, the lower wire segment in the intersection where the windings cross each other in the inductor element can be formed by the first wiring formed on the semiconductor substrate with the first insulating film interposed therebetween. Accordingly, by isolating the first wiring from the semiconductor substrate, an eddy current generated in the substrate can be suppressed and a high Q-factor can be obtained. Moreover, the substrate-wiring parasitic capacitance is reduced and a high self resonant frequency can be obtained.

According to the present invention, each winding of the inductor element has a two-layer structure of the first wiring and the second wiring. Accordingly, the series resistance of each winding can be reduced, whereby loss resulting from the resistance can be significantly reduced. As a result, a high self resonant frequency, high Q-factor high-frequency inductor element can be implemented. The use of this high frequency inductor element can improve performance, power consumption, and the like of RF circuits such as oscillators and low noise amplifiers.

In other words, the inductor element of the present invention has excellent characteristics such as a high Q-factor and a high self resonant frequency. The inductor element of the present invention is therefore useful as an inductor included in, for example, a semiconductor device of a high frequency RF circuit, and is especially useful as an inductor for which improved performance in high frequency operation is required.

### BRIEF DESCRIPTION OF THE DRAWINGS

FIG. 1 is a diagram showing a planar shape of an inductor element in a semiconductor device according to a first embodiment of the present invention;

FIG. 2A is a cross-sectional view taken along line A-A′ in FIG. 1 and FIG. 2B is a cross-sectional view taken along line B-B′ in FIG. 1;

FIGS. 3A, 3B, and 3C are cross-sectional views illustrating each step of a manufacturing method of a semiconductor device according to a first embodiment of the present invention;

FIG. 4 is a diagram showing a planar shape of an inductor element in a semiconductor device according to a second embodiment of the present invention;

FIG. 5A is an enlarged plan view showing an intersection of windings and a peripheral region thereof in an inductor element in the semiconductor device according to the second embodiment of the present invention, FIG. 5B is a cross-sectional view taken along line A-A′ in FIG. 5A, and FIG. 5C is a cross-sectional view taken along line B-B′ in FIG. 5A;

FIG. 6 is a plan view of a conventional inductor element; and

FIG. 7 is a cross-sectional view taken along line VII-VII in FIG. 6.

### DETAILED DESCRIPTION OF THE PREFERRED EMBODIMENTS

### First Embodiment

Hereinafter, a semiconductor device according to a first embodiment of the present invention, more specifically, a semiconductor device including an inductor element, will be described with reference to the accompanying drawings.

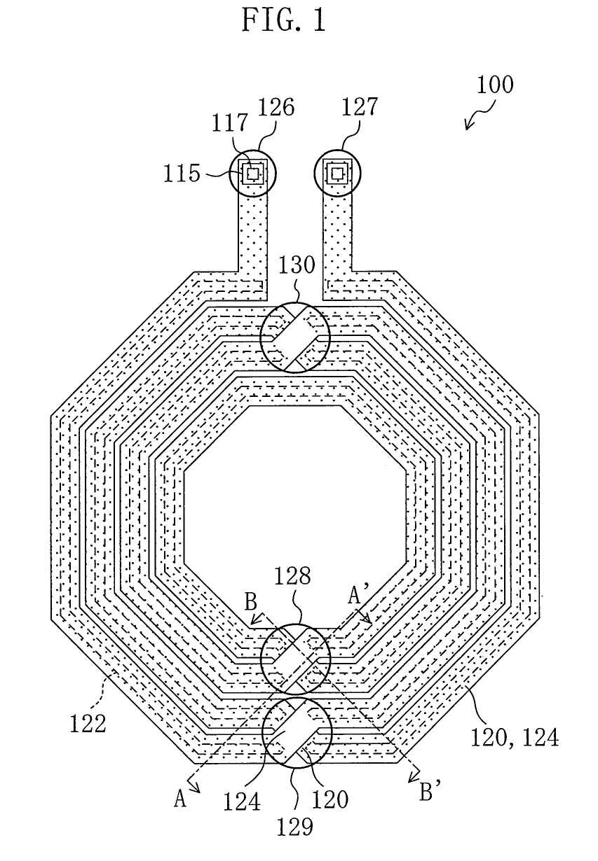

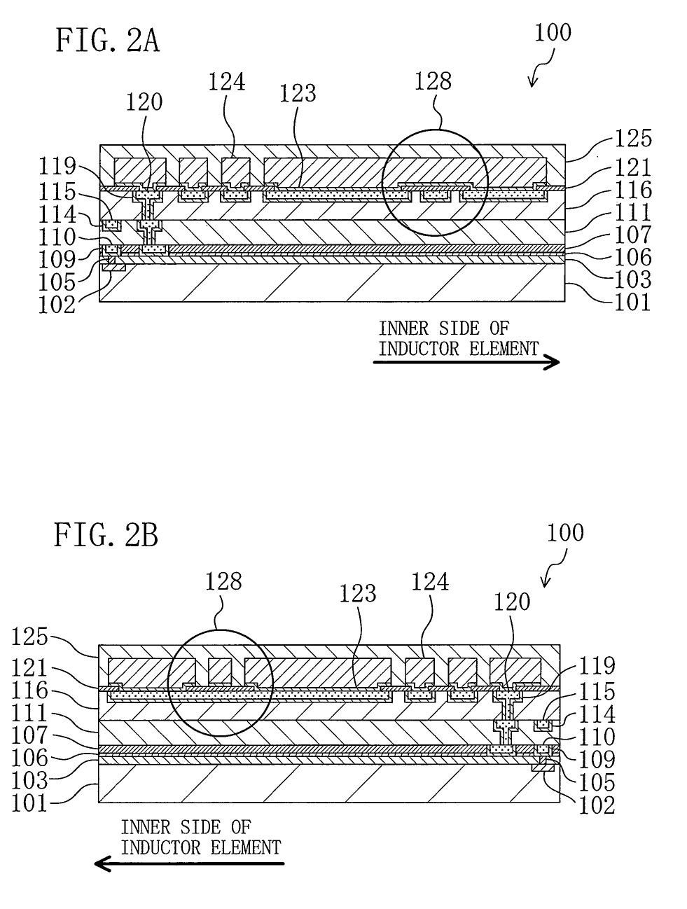

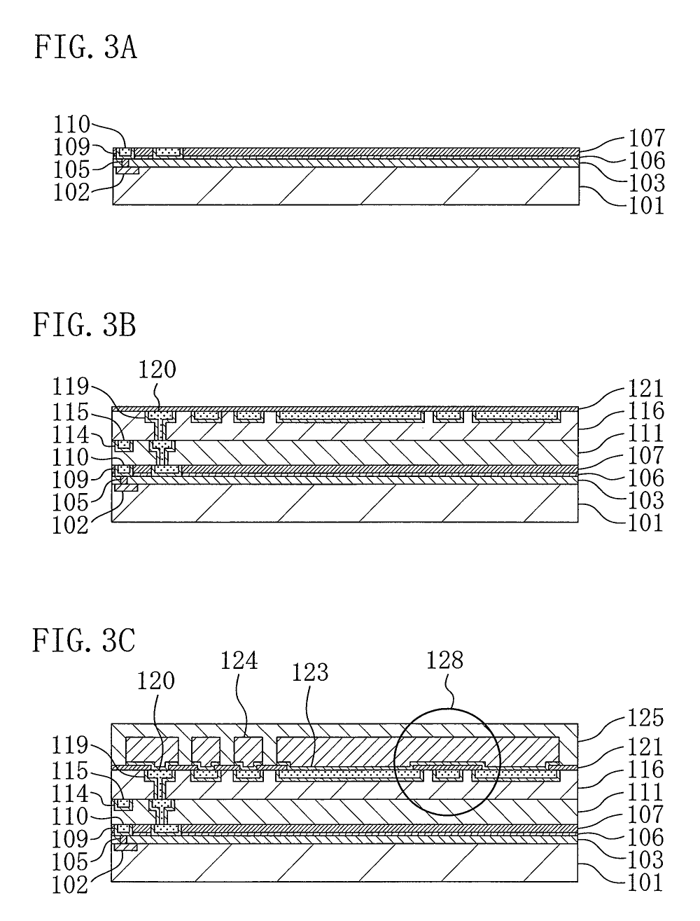

FIG. 1 is a diagram showing a planar shape of an inductor element in a semiconductor device of the present embodiment. FIG. 2A is a cross-sectional view taken along line A-A′ in FIG. 1, and FIG. 2B is a cross-sectional view taken along line B-B′ in FIG. 1. Note that in the description with reference to FIGS. 1, 2A, and 2B, main components of the inductor element will be mainly described, and other components of the inductor element will be described later in a manufacturing method shown in FIGS. 3A through 3C.

As shown in FIG. 1 and FIGS. 2A, and 2B, each winding of a spiral inductor element 100 is formed by two of the following four metal wirings formed over a semiconductor substrate 101: a lowermost-layer metal wiring 110, a lower-layer metal wiring 115, an upper-layer metal wiring 120, and an uppermost-layer metal wiring 124. More specifically, each winding of the spiral inductor element 100 is formed by the uppermost-layer metal wiring 124 and the upper-layer metal wiring 120 which are electrically connected to each other through a groove-like opening 122 formed in an uppermost-layer insulating film 121. The inductor element 100 has four windings, and includes three intersections 128, 129, and 130 from one end 126 to the other end 127 where the windings cross each other.

As shown in FIG. 2A, the upper-layer metal wiring 120 formed over an upper-layer insulating film 116 is separated in the intersection 128. An upper wire segment in the intersection 128 (a wire segment crossing above the other wire segment in the intersection 128) is therefore formed only by the uppermost-layer metal wiring 124 formed over the uppermost-layer insulating film 121. As shown in FIG. 2B, on the other hand, the uppermost-layer metal wiring 124 formed over the uppermost-layer insulating film 121 is separated in the intersection 128. A lower wire segment in the intersection 128 (a wire segment crossing under the other wire segment in the intersection 128) is therefore formed only by the upper-layer metal wiring 120 formed over the upper-layer insulating film 116. Note that the uppermost-layer metal wiring 124 serving as the upper wire segment in the intersection 128 and the upper-layer metal wiring 120 serving as the lower wire segment in the intersection 128 are electrically insulated from each other by the uppermost-layer insulating film 121. The same structure as that of the intersection 128 described above is provided in intersections 129 and 130.

Hereinafter, a manufacturing method of the semiconductor device of the present embodiment shown in FIG. 1 and FIGS. 2A and 2B will be described with reference to the drawings. FIGS. 3A through 3C are cross-sectional views illustrating each step of the manufacturing method of the semiconductor device (the semiconductor device including an inductor element) of the present embodiment. FIGS. 3A through 3C show cross-sectional structures taken along line A-A′ in FIG. 1. Note that, in FIGS. 3A through 3C, the same components as those of FIG. 1 and FIGS. 2A and 2B will be denoted by the same reference numerals and overlapping description of the structure of the inductor element 100 and the like will be omitted.

First, as shown in FIG. 3A, a diffusion layer 102 is formed by diffusing N-type or P-type impurities in a surface portion of a semiconductor substrate 101. A field oxide film 103 is then formed on the whole surface of the semiconductor substrate 101 by thermal oxidation or a CVD (Chemical Vapor Deposition) method. The field oxide film 103 is then partially etched to form a contact hole reaching the diffusion layer 102. A tungsten plug 105 is then embedded in the contact hole. A plasma silicon nitride film (hereinafter, referred to as P—SiN film) 106 having a thickness of, for example, about 50 nm is then deposited on the field oxide film 103 including on the tungsten plug 105. A lowermost-layer insulating film 107 having a thickness of about 250 nm is then deposited on the P—SiN film 106. The lowermost-layer insulating film 107 is made of, for example, an oxide film containing fluorine and the like. The P—SiN film 106 and the lowermost-layer insulating film 107 are selectively etched to form a wiring groove, and a barrier metal 109 containing a metal such as a tantalum (Ta)-based metal or a titanium (Ti)-based metal is then deposited on the bottom surface and the wall surface of the wiring groove. By using the barrier metal 109 as a plating electrode, copper, for example, is embedded in the wiring groove by electroplating. The surface of the embedded copper is planarized by, for example, a CMP (Chemical Mechanical Polishing) method to form a lowermost-layer metal wiring 110.

As shown in FIG. 3B, a lower-layer insulating film 111 made of, for example, a P—SiN film or a plasma TEOS (tetoraethylorthosilicate) film is deposited on the whole surface of the lowermost-layer insulating film 107 including on the lowermost-layer metal wiring 110. The surface of the lower-layer insulating film 111 is then planarized by, for example, a CMP method. The lower-layer insulating film 111 is then selectively etched to form a via hole reaching the lowermost-layer metal wiring 110 and a wiring groove. A barrier metal 114 made of a metal such as a Ta-based metal or a Ti-based metal is then deposited on the respective bottom surfaces and wall surfaces of the via hole and the wiring groove. By using the barrier metal 114 as a plating electrode, copper, for example, is embedded in the via hole and the wiring groove by electroplating. The surface of the embedded copper is then planarized by, for example, a CMP method to form a lower-layer metal wiring 115. An upper-layer insulating film 116 made of, for example, a P—SiN film or a plasma TEOS film is then deposited on the whole surface of the lower-layer insulating film 111 including on the lower-layer metal wiring 115. The surface of the upper-layer insulating film 116 is then planarized by, for example, a CMP method. The upper-layer insulating film 116 is then selectively etched to form a via hole (via hole 117 in FIG. 1) reaching the lower-layer metal wiring 115 and a wiring groove. A barrier metal 119 is then deposited on the respective bottom surfaces and wall surfaces of the via hole and the wiring groove by, for example, a sputtering method. By using the barrier metal 119 as a plating electrode, copper, for example, is embedded in the via hole and the wiring groove by electroplating. The surface of the embedded copper is then planarized by, for example, a CMP method to form an upper-layer metal wiring 120. An uppermost-layer insulating film 121 made of, for example, a P—SiN film is then formed with a thickness of about 300 nm on the whole surface of the upper-layer insulating film 116 including on the upper-layer metal wiring 120.

As shown in FIG. 3C, the uppermost-layer insulating film 121 is then selectively etched to form a groove-like opening (opening 122 in FIG. 1) reaching the upper-layer metal wiring 120. A Ti-based metal film having a thickness of about 0.1 μm and an aluminum film having a thickness of about 3 μm are then sequentially deposited by, for example, a sputtering method on the whole surface of the uppermost-layer insulating film 121 including the opening. The aluminum film and the Ti-based metal film are then patterned by photolithography and dry etching to form a barrier metal 123 and an uppermost-layer metal wiring 124. The upper-layer metal wiring 120 and the uppermost-layer metal wiring 124 are electrically connected to each other through the groove-like opening (opening 122 in FIG. 1) in the uppermost-layer insulating film 121 except in the intersection 128. A protective film 125 made of, for example, a P—SiN film or a plasma SiON film is then formed on the whole surface of the uppermost-layer insulating film 121 including on the uppermost-layer metal wiring 124. The inductor element is thus completed.

As described above, according to the first embodiment, the upper-layer metal wiring 120 formed over the semiconductor substrate 101 with the upper-layer insulating film 116 and the like interposed therebetween and the uppermost-layer metal wiring 124 formed over the upper-layer metal wiring 120 with the uppermost-layer insulating film 121 interposed therebetween are electrically connected to each other through the groove-like opening 122 formed in the uppermost-layer insulating film 121. Each winding of the inductor element 100 is thus formed. Accordingly, by separating the uppermost-layer metal wiring 124 in each intersection 128 through 130, the lower wire segment in each intersection 128 through 130 can be formed by the upper-layer metal wiring 120, that is, the upper-layer metal wiring 120 formed over the semiconductor substrate 101 with the upper-layer insulating film 116 and the like interposed therebetween. Since the upper-layer metal wiring 120 can be isolated from the semiconductor substrate 101, an eddy current generated in the semiconductor substrate 101 during power supply operation can be suppressed. As a result, loss due to the eddy current can be suppressed, whereby a high Q-factor inductor element 100 can be implemented. Moreover, the upper-layer metal wiring 120 serving as the lower wire segment in each intersection 128 through 130 can be isolated from the semiconductor substrate 101. Accordingly, substrate-wiring parasitic capacitance can be reduced, and the influence of capacitive coupling can be suppressed. As a result, an inductor element 100 having a high self resonant frequency can be implemented.

According to the first embodiment, each winding of the inductor element 100 except the intersections 128 though 130 has a two-layer structure of the uppermost-layer metal wiring 124 and the upper-layer metal wiring 120 which are electrically connected to each other through the opening 122. Therefore, a substantial thickness of each winding can be increased and the series resistance of each winding can be reduced. As a result, loss due to the resistance can be significantly reduced. Since the self resonant frequency and the Q-factor of the inductor element 100 can further be improved, a high performance high frequency inductor element can be implemented. As a result, performance, power consumption, and the like of an RF circuit such as an oscillator and a low noise amplifier can be improved.

Note that, in the first embodiment, the barrier metals 109, 114, and 119 may be made of, for example, a tantalum nitride (TaN) film having a thickness of about 25 nm, and the lowermost-layer metal wiring 110, the lower-layer metal wiring 115, and the upper-layer metal wiring 120 may be made of, for example, a copper film having a thickness of about 500 nm.

In the first embodiment, the lower-layer insulating film 111 and the upper-layer insulating film 116 are formed by depositing, for example, a plasma TEOS film of a thickness of about 400 nm and planarizing the plasma TEOS film by a CMP method. Therefore, film reduction occurs in the lower-layer insulating film 111 and the upper-layer insulating film 116. In order to prevent such film reduction and reduce the substrate-wiring parasitic capacitance, an oxide film may be additionally deposited after the plasma TEOS film of the lower-layer insulating film 111 and the upper-layer insulating film 116 is planarized.

In the first embodiment, for example, an aluminum film is deposited as the uppermost-layer metal wiring 124 by a sputtering method. However, a low-specific resistance film such as gold, silver, or copper may alternatively be formed by electroplating as the uppermost-layer metal wiring 124.

A four-turn inductor element 100 having four windings is described in the first embodiment. However, the inductor element 100 may have any number of windings of at least 2 (as long as the inductor element 100 has at least one intersection). In the first embodiment, four metal wirings, that is, the lowermost-layer metal wiring 110, the lower-layer metal wiring 115, the upper-layer metal wiring 120, and the uppermost-layer metal wiring 124, are formed over the semiconductor substrate 101, and the inductor element 100 is formed by using two of the four metal wirings, that is, the uppermost-layer metal wiring 124 and the upper-layer metal wiring 120. However, the present invention is not limited to this structure. In other words, the total number of wiring layers in the device and the types of wiring layers used to form the inductor element 100 are not specifically limited as long as there are wirings of two layers for forming the inductor element 100 and at least one layer of insulating film is formed between the lower one of the two wirings and the semiconductor substrate 101.

### Second Embodiment

Hereinafter, a semiconductor device according to a second embodiment of the present invention, more specifically, a semiconductor device including an inductor element, will be described with reference to the drawings.

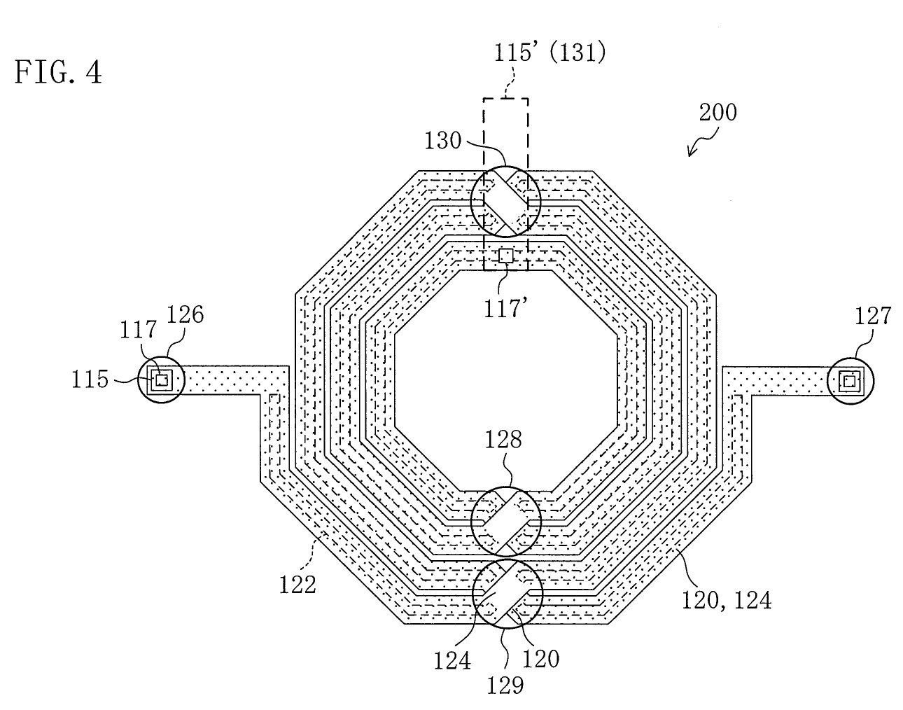

FIG. 4 shows a planar shape of the inductor element in the semiconductor device of the present embodiment. Note that, in FIG. 4, the same components as those of the first embodiment shown in FIG. 1 and FIGS. 2A and 2B will be denoted by the same reference numerals and overlapping description will be omitted.

An inductor element 200 of the present embodiment shown in FIG. 4 is different from the inductor element 100 of the first embodiment shown in FIG. 1 and FIGS. 2A and 2B in that a tap terminal 131 is provided in the midpoint between one end 126 and the other end 127 of the inductor element 200 of the present embodiment. The tap terminal 131 is formed by extending one portion of windings (more specifically, one portion of an upper-layer metal wiring 120) of the inductor element 200 to a lower-layer metal wiring 115′. The inductor element 200 having three and a half windings as a whole can thus be divided into two inductors having similar characteristics, and each inductor can be connected to the outside.

More specifically, as shown in FIG. 4, the upper-layer metal wiring 120 forming the windings of the inductor element 200 and the lower-layer metal wiring 115′ are electrically connected to each other through a via hole 117′. The via hole 117′ is formed in an upper-layer insulating film 116 over a semiconductor substrate 101. The tap terminal 131 is formed by the lower-layer metal wiring 115′. As a result, two inductors of the inductor element 200 are provided between one end 126 of the inductor element 200 and the tap terminal 131 and between the other end 127 of the inductor element 200 and the tap terminal 131, respectively.

As described above, the second embodiment has the following effects in addition to the effects of the first embodiment. In the second embodiment, the tap terminal 131 is formed at the midpoint between one end 126 and the other end 127 of the inductor element 200 by extending one portion of the windings of the inductor element 200 to the lower-layer metal wiring 115′. Accordingly, two inductors having similar characteristics can be easily provided between one end 126 of the inductor element 200 and the tap terminal 131 and between the other end 127 of the inductor element 200 and the tap terminal 131, respectively. Moreover, in these two inductors, the influence of capacitive coupling generated between the upper-layer metal wiring 120 and the semiconductor substrate 101 in each intersection of the windings can be suppressed, and loss resulting from the loss of eddy current generated in the semiconductor substrate 101 during power supply operation can be suppressed, as described in the first embodiment. Two high Q-factor, high self-resonant-frequency inductors having excellent characteristics can therefore be easily implemented.

Note that, in the second embodiment, the lower-layer metal wiring 115′, which is formed one-layer lower than the upper-layer metal wiring 120 in the lower layer portion of the windings of the inductor element 200, is used as the tap terminal 131. However, the lowermost-layer metal wiring 110 which is formed two-layers lower than the upper-layer metal wiring 120 may alternatively be used as the tap terminal 131. Alternatively, an additional wiring may be formed one-layer above the uppermost-layer metal wiring 124 in the upper layer portion of the windings of the inductor element 200, and may be used as the tap terminal 131.

In the second embodiment, the inductor element 200 is divided into two inductors by providing one tap terminal 131. However, the inductor element 200 may be divided into three or more inductors by providing two or more tap terminals.

### Third Embodiment

Hereinafter, a semiconductor device according to a third embodiment of the present invention, more specifically, a semiconductor device including an inductor element, will be described with reference to the drawings.

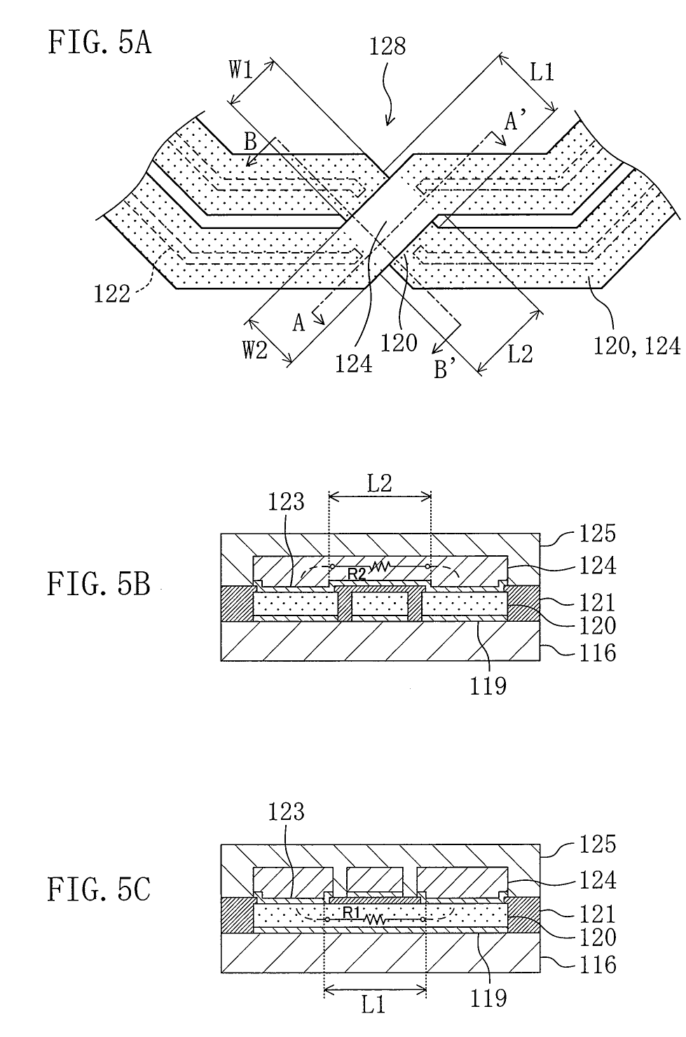

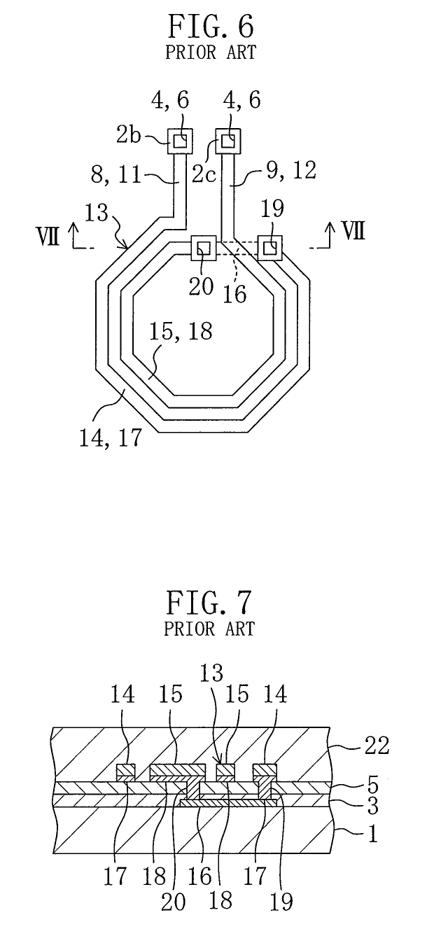

FIG. 5A is an enlarged plan view showing an intersection of windings (corresponding to the intersection 128 of the first and second embodiments) and a peripheral region thereof in the inductor element of the semiconductor device of the present embodiment. FIG. 5B is a cross-sectional view taken along line A-A′ in FIG. 5A. FIG. 5C is a cross-sectional view taken along line B-B′ in FIG. 5A. Note that FIGS. 5B and 5C show the upper-layer insulating film 116 of the first embodiment shown in FIGS. 2A and 2B and a portion above the upper-layer insulating film 116. A portion under the upper-layer insulating film 116 is basically the same as that in the first embodiment. In FIGS. 5A through 5C, the same components as those of the first embodiment shown in FIG. 1 and FIGS. 2A and 2B are denoted by the same reference numerals and overlapping description will be omitted.

As shown in FIGS. 5A through 5C, in the present embodiment, an upper-layer metal wiring 120 formed over an upper-layer insulating film 116 is separated in an intersection 128, as in the first embodiment. An upper wire segment in the intersection 128 (a wire segment crossing above the other wire segment in the intersection 128) is therefore formed only by an uppermost-layer metal wiring 124 formed over an uppermost-layer insulating film 121. The uppermost-layer metal wiring 124 formed over the uppermost-layer insulating film 121 is separated in the intersection 128. A lower wire segment in the intersection 128 (a wire segment crossing under the other wire segment in the intersection 128) is therefore formed only by the upper-layer metal wiring 120 formed over the upper-layer insulating film 116. Note that the uppermost-layer metal wiring 124 serving as the upper wire segment in the intersection 128 and the upper-layer metal wiring 120 serving as the lower wire segment in the intersection 128 are electrically insulated from each other by the uppermost-layer insulating film 121.

Note that, in FIGS. 5A through 5C, L1 indicates the separation length of the uppermost-layer metal wiring 124 over the upper-layer metal wiring 120 as the lower wire segment in the intersection 128 (the length of a region where the uppermost-layer metal wiring 124 electrically connected to the upper-layer metal wiring 120 is not formed). W1 indicates the width of the upper-layer metal wiring 120 as the lower wire segment in the intersection 128. L2 indicates the separation length of the upper-layer metal wiring 120 under the uppermost-layer metal wiring 124 as the upper wire segment in the intersection 128 (the length of a region where the upper-layer metal wiring 120 electrically connected to the uppermost-layer metal wiring 124 is not formed). W2 indicates the width of the uppermost-layer metal wiring 124 as the upper wire segment in the intersection 128.

R1 indicates the resistance of the upper-layer metal wiring 120 as the lower wire segment in the intersection 128. R2 indicates the resistance of the uppermost-layer metal wiring 124 as the upper wire segment in the intersection 128.

Hereinafter, the differences of the inductor element of the present embodiment shown in FIGS. 5A through 5C from the inductor element 100 of the first embodiment shown in FIG. 1 and FIGS. 2A and 2C will be described in terms of the manufacturing method.

In the present embodiment, the same steps as those of the first embodiment are performed until formation of the lower-layer metal wiring 115 (see FIGS. 3A and 3B and description thereof). An upper-layer insulating film 116 made of, for example, a P—SiN film or a plasma TEOS film is then deposited on the whole surface of the lower-layer insulating film 111 including on the lower-layer metal wiring 115. The surface of the upper-layer insulating film 116 is then planarized by, for example, a CMP method. As shown in FIGS. 5B and 5C, a Ti-based metal film having a thickness of about 0.1 μm and an aluminum film having a thickness of about 3 μm are then deposited by, for example, a sputtering method on the whole surface of the upper-layer insulating film 116. The aluminum film and the Ti-based metal film are then patterned by photolithography and dry etching to form a barrier metal 119 and an upper-layer metal wiring 120. An uppermost-layer insulating film 121 made of, for example, a plasma TEOS film of a thickness of about 2 μm is then formed on the whole surface of the upper-layer insulating film 116 including on the upper-layer metal wiring 120. The uppermost-layer insulating film 121 is then selectively etched to form a groove-like opening (opening 122 in FIG. 5A) reaching the upper-layer metal wiring 120. A Ti-based metal film having a thickness of about 0.1 μm and an aluminum film having a thickness of about 3 μm are then sequentially deposited by, for example, a sputtering method on the whole surface of the uppermost-layer insulating film 121 including the opening. The aluminum film and the Ti-based metal film are then patterned by photolithography and dry etching to form a barrier metal 123 and an uppermost-layer metal wiring 124. The upper-layer metal wiring 120 and the uppermost-layer metal wiring 124 are electrically connected to each other except in the intersection 128 through the groove-like opening (opening 122 in FIG. 5A) in the uppermost-layer insulating film 121. A protective film 125 made of, for example, a P—SiN film or a plasma SiON film is then formed on the whole surface of the uppermost-layer insulating film 121 including on the uppermost-layer metal wiring 124. The inductor element is thus completed.

As described above, in the present embodiment, the upper metal wiring 120 and the uppermost-layer metal wiring 124 are made of the same metal material with the same thickness. The width W1 of the upper-layer metal wiring 120 as the lower wire segment in the intersection 128 and the width W2 of the uppermost-layer metal wiring 124 as the upper wire segment in the intersection 128 have the same value (e.g., about 8 μm). Moreover, the separation length L1 of the uppermost-layer metal wiring 124 over the upper-layer metal wiring 120 as the lower wire segment in the intersection 128 and the separation length L2 of the upper-layer metal wiring 120 under the uppermost-layer metal wiring 124 as the upper wire segment in the intersection 128 have the same value (e.g., about 18 μm). Accordingly, in the present embodiment, the electric resistance R1 of the upper-layer metal wiring 120 as the lower wire segment in the intersection 128 and the electric resistance R2 of the uppermost-layer metal wiring 124 as the upper wire segment in the intersection 128 have substantially the same value.

The inductor element of the third embodiment therefore has the following effects in addition to the effects of the first embodiment. Since the respective series resistances when viewed from both ends of the inductor element are uniform and equal, respective Q-factor losses resulting from the resistance are therefore equal when viewed from both ends of the inductor element. Accordingly, a high frequency inductor element having excellent symmetry can be implemented.

Note that, in the third embodiment as well, by connecting a tap terminal at the midpoint between one end and the other end of the inductor element as in the second embodiment, two high frequency inductors having similar characteristics can be easily provided between the one end and the tap terminal and between the other end and the tap terminal, respectively.

In the third embodiment, the upper-layer metal wiring 120 and the uppermost-layer metal wiring 124 are made of the same metal material with the same dimensions. However, the upper-layer metal wiring 120 and the uppermost-layer metal wiring 124 may alternatively be made of different conductive materials from each other. In this case, by appropriately adjusting the dimensions such as the thickness of each wiring, the electric resistance R1 of the upper-layer metal wiring 120 as the lower wire segment in the intersection 128 and the electric resistance R2 of the uppermost-layer metal wiring 124 as the upper wire segment in the intersection 128 can be made substantially equal to each other. The same effects as those of the present embodiment can therefore be obtained.

For example, it is herein assumed that the upper-layer metal wiring 120 is made of a copper metal having a specific resistance ρ1 and the uppermost-layer metal wiring 124 is made of an aluminum metal having a specific resistance ρ2. Provided that t1 is the thickness of the upper-layer metal wiring 120 and t2 is the thickness of the uppermost-layer metal wiring 124 and each wiring has the same width and the same separation length at the intersection, the same effects as those of the present embodiment can be obtained by setting the thickness of each wiring by the following formula (2):

t2=t1×ρ2/ρ1 (2).

Provided that ρ1 is 1.72×10⁻⁸ Ω·m, p2 is 2.75×10⁻⁸ Ω·m, and t1 is 1 μm, t2 (the thickness of the uppermost-layer metal wiring 124 made of an aluminum metal) is set to about 1.6 μm according to the formula (2). In this case, the electric resistance R1 of the upper-layer metal wiring 120 as the lower wire segment in the intersection 128 and the electric resistance R2 of the uppermost-layer metal wiring 124 as the upper wire segment in the intersection 128 can be made equal to each other even when the upper-layer metal wiring 120 and the uppermost-layer metal wiring 124 are made of different metal wires from each other. Accordingly, respective Q-factor losses resulting from the resistance become equal to each other when viewed from both ends of the inductor element. An inductor element having excellent symmetry can therefore be implemented.

What is claimed is:

1. A semiconductor device including an inductor element formed on a semiconductor substrate, wherein
the inductor element is formed in a spiral shape so as to have a plurality of windings which cross each other three-dimensionally at least in one intersection on the semiconductor substrate,
each of the plurality of windings is formed by a first wiring formed on the semiconductor substrate with a first insulating film interposed therebetween and a second wiring formed on the first wiring with a second insulating film interposed therebetween,
the first wiring and the second wiring are electrically connected to each other in a region other than the intersection of the plurality of windings through an opening formed in the second insulating film,
a lower wire segment in the intersection is formed only by the first wiring by separating the second wiring in the intersection,
an upper wire segment in the intersection is formed only by the second wiring by separating the first wiring in the intersection, and
the first wiring of the lower wire segment and the second wiring of the upper wire segment are electrically insulated from each other by the second insulating film.

2. The semiconductor device according to claim 1, wherein a third wiring is formed between the semiconductor substrate and the first insulating film.

3. The semiconductor device according to claim 1, further comprising a tap terminal formed by extending at least one portion of the plurality of windings to a wiring of a layer lower than that of the first wiring or to a wiring of a layer higher than that of the second wiring.

4. The semiconductor device according to claim 3, wherein the tap terminal is provided at a midpoint between one end and another end of the inductor element.

5. The semiconductor device according to claim 1, wherein the first wiring of the lower wire segment and the second wiring of the upper wire segment have a substantially same electric resistance.

6. The semiconductor device according to claim 5, wherein the first wiring of the lower wire segment and the second wiring of the upper wire segment are made of substantially a same material with substantially same dimensions.
